(19) United States
(12) Patent Application Publication
(10) Pub. No.: US 2024/0125555 A1
(43) Pub. Date: Apr. 18, 2024

(54) COMPOUND EVAPORATIVE COOLING TOWER AND DATA CENTER

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN); Xiaogang SUN, Zhangjiakou City (CN)

(21) Appl. No.: 18/487,982

(22) Filed: Oct. 16, 2023

(30) Foreign Application Priority Data
Oct. 18, 2022 (CN) 202211273231.0

(51) Int. Cl. F28C 1/14; H05K 7/20

(52) U.S. Cl. CPC F28C 1/14; H05K 7/20309; H05K 7/20327; H05K 7/20345; H05K 7/20827; F28C 2001/006

(57) ABSTRACT

An embodiment of the present disclosure provides a compound evaporative cooling tower and a data center, relating to the field of cooling tower technology. The compound evaporative cooling tower includes an air-inlet grille, a precooling module, a first spray module, a cooling module, a direct evaporative heat exchanger, a second spray module, a water collector, and an outdoor fan. The precooling module is arranged on an inner side of the air-inlet grille. The first spray module is arranged above the precooling module, and the second spray module is arranged above the direct evaporative heat exchanger. The cooling module is arranged below the direct evaporative heat exchanger and includes a plurality of cooling sub-modules.

### CROSS-REFERENCE TO RELATED APPLICATION

This application claims priority to Chinese Patent Application No. 202211273231.0, titled “COMPOUND EVAPORATIVE COOLING TOWER AND DATA CENTER” and filed to the China National Intellectual Property Administration on Oct. 18, 2022, the entire contents of which are incorporated herein by reference.

### TECHNICAL FIELD

The present disclosure relates to the field of cooling tower technology, and more particularly, to a compound evaporative cooling tower and a data center.

### BACKGROUND

IT devices in a data center may emit a lot of heat when the IT devices are running. With the development of scale and integration of the data center, heat generated in the IT devices in the data center is increasing day by day. If the heat generated is not dissipated in time, the IT devices in the data center may go wrong or even go down due to high temperature, which may adversely affect normal operation of the data center.

To ensure the normal operation of the devices, an air conditioning system may be set up for the data center to cool a computer room of the data center. The existing air conditioning system of the data center consumes a lot of energy, accounting for a large proportion of total energy consumption of the data center. For a large data center, use of the existing air conditioning system is costly, and has a poor cooling effect.

### SUMMARY

To solve some or all problems existing in the prior art, an embodiment of the present disclosure provides a compound evaporative cooling tower and a data center. The technical solutions are as follows.

In a first aspect, there is provided a compound evaporative cooling tower, which includes an air-inlet grille, a precooling module, a spray circulating pump, a first spray module, a cooling module, a direct evaporative heat exchanger, a second spray module, a water collector, and an outdoor fan.

The precooling module is arranged on an inner side of the air-inlet grille.

The first spray module is arranged above the precooling module, and the second spray module is arranged above the direct evaporative heat exchanger.

The cooling module is arranged below the direct evaporative heat exchanger, and the cooling module includes a plurality of cooling sub-modules.

Further, the precooling module includes a precooling wet film and an indirect evaporative cooler, where the indirect evaporative cooler is arranged on an inner side of the precooling wet film.

Further, the cooling tower also includes at least one spray circulating pump, where the first spray module and the second spray module are connected to the at least one spray circulating pump through a pipe.

Further, the first spray module is connected to a first spray circulating pump, and the second spray module is connected to a second spray circulating pump.

Further, the cooling module includes a natural cooling sub-module and a mechanical cooling sub-module.

Further, the natural cooling sub-module includes an ordinary evaporative cooling coil and a cooling water circulating pump connected through a pipe.

Further, the mechanical cooling sub-module includes a fluorine pump evaporative cooling coil, a fluorine pump, and a compressor connected through a pipe.

Further, the water collector is arranged above the second spray module, and the outdoor fan is arranged at a top of the cooling tower.

Further, the cooling tower also includes an air precooler arranged above the first spray module.

In a second aspect, there is provided a data center, which includes the compound evaporative cooling tower as described in the first aspect and a server room.

Compared with a traditional evaporative cooling system air conditioner, by using compound evaporative cooling principles, the compound evaporative cooling tower and the data center provided by the present disclosure can improve the cooling efficiency of the air conditioner system, and further reduce the energy consumption in the operation of the data center. In addition, the present disclosure integrates multiple sets of standalone cold sources to cool the same data center, thus further improving the cooling effect of the air conditioning system and realizing rapid delivery of the air conditioning system based on cooling by the multiple sets of cold sources.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a compound evaporative cooling tower provided by an embodiment of the present disclosure; and

FIG. 2 is a schematic diagram of an operating principle of a precooling module provided by an embodiment of the present disclosure.

### DETAILED DESCRIPTION

To make the objectives, technical solutions and advantages of the present disclosure clearer, the embodiments of the present disclosure will be further described below in detail with reference to the accompanying drawings. Terms such as “upper”, “above”, “lower”, “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “sliding connection”, “fixed” and “socket” should be understood broadly. For example, the “connection” may be a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

An embodiment of the present disclosure provides a compound evaporative cooling tower, which includes an air-inlet grille, a precooling module, a spray circulating pump, a first spray module, a cooling module, a direct evaporative heat exchanger, a second spray module, a water collector, and an outdoor fan. The precooling module is arranged on an inner side of the air-inlet grille. The first spray module is arranged above the precooling module, and the second spray module is arranged above the direct evaporative heat exchanger. The cooling module is arranged below the direct evaporative heat exchanger.

For the ease of description, a spray module for precooling the precooling module may be referred to as the first spray module, and a spray module for cooling the direct evaporative heat exchanger may be referred to as the second spray module.

In implementation, the first spray module is arranged above the precooling module, and the second spray module is arranged above the direct evaporative heat exchanger. That is, the first spray module is farther away from a ground than the precooling module, which is convenient for the first spray module to spray water to the precooling module through a nozzle. The second spray module is farther away from the ground than the direct evaporative heat exchanger, which is convenient for the second spray module to spray the water to the direct evaporative heat exchanger through the nozzle. Number of nozzles may be set according to actual needs, which is not limited in the present disclosure.

The precooling module may be arranged on the inner side of the air-inlet grille. In other words, the precooling module is closer to a center of the cooling tower than the air-inlet grille. In this way, outdoor air may enter the precooling module through the air-inlet grille. The air-inlet grille may also be referred to as an air-inlet window, and may be made of PVC, stainless steel, and so on.

In one embodiment, the precooling module may further include a precooling wet film and an indirect evaporative cooler arranged on an inner side of the precooling wet film. That is, the indirect evaporative cooler is closer to the center of the cooling tower than the inner side of the precooling wet film.

In one embodiment, the cooling tower may further include at least one spray circulating pump, where the first spray module and the second spray module are connected to the at least one spray circulating pump through a pipe.

For example, the first spray module for precooling the precooling module and the second spray module for cooling the direct evaporative heat exchanger may share one or a group of spray circulating pumps. In this case, the first spray module, the second spray module and the shared spray circulating pump may be communicated through a pipe and may share a water tray (or a water collecting tray).

Of course, the first spray module and the second spray module may also occupy one or a group of spray circulating pump, respectively. For the ease of description, the spray circulating pump exclusive to the first spray module may be referred to as a first spray circulating pump, and the spray circulating pump exclusive to the second spray module may be referred to as a second spray circulating pump. In this case, the first spray module is connected to the first spray circulating pump, and the second spray module is connected to the second spray circulating pump. Thus, the first spray module and the second spray module respectively belong to two different spray systems, each of which includes parts such as the nozzle, the pipe, the pump, and the water tray, etc.

In one embodiment, the cooling module may include a plurality of cooling sub-modules. In this way, multiple sets of cold sources may be simultaneously provided to cool a data center computer room, which can improve heat dissipation effects of the air conditioning system on the data center computer room. Specifically, some or all the cooling sub-modules may be enabled according to the actual needs to cool the data center computer room.

The plurality of cooling sub-modules may include one or more natural cooling sub-modules and/or one or more mechanical cooling sub-modules.

In one embodiment, the natural cooling sub-module may include an ordinary evaporative cooling coil and a cooling water circulating pump connected through a pipe to provide a cooling water source to the data center. The mechanical cooling sub-module may include a fluorine pump evaporative cooling coil, a fluorine pump and a compressor connected through a pipe, to provide a refrigerant source to the data center.

In one embodiment, the water collector is arranged above the second spray module, and the outdoor fan is arranged on the top of the cooling tower.

The water collector may be configured to recover liquid water carried in part of evaporated water vapor, and the outdoor fan may be configured to guide air flowing through the cooling module into atmosphere.

In one embodiment, the cooling tower further includes an air precooler arranged above the first spray module, and the air precooler may be configured to guide the air flowing through the precooling module into the atmosphere.

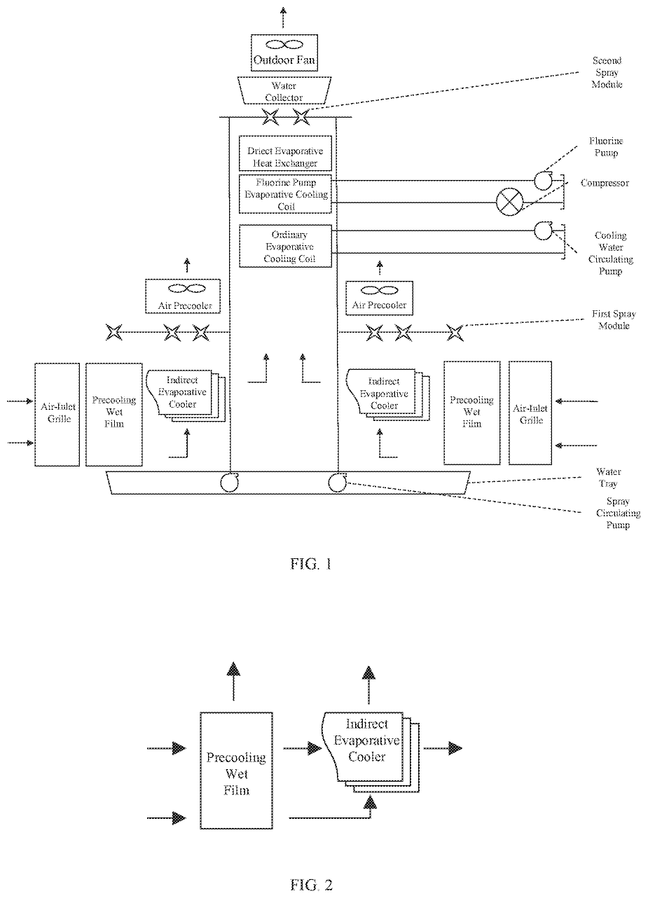

In one embodiment, referring to FIG. 1 (arrows in the figure may indicate air flow directions), after flowing through the air-inlet grille and being successively precooled by the precooling wet film and the indirect evaporative cooler, the outdoor air cools the cooling module, then cools cooling water on the direct evaporative heat exchanger, and then is discharged into the atmosphere through the water collector and the outdoor fan. The precooling wet film and the indirect evaporative cooler may cool the outdoor air, such that a dry-bulb temperature thereof may be reduced as close as possible to a wet-bulb temperature. Reference may be made to FIG. 2 for an operating principle of the precooling module, where arrows indicate flow directions of the outdoor air at the precooling module in this embodiment. The direct evaporative heat exchanger can cool the cooling water, such that its temperature is as close as possible to the wet-bulb temperature.

The natural cooling sub-module shown in FIG. 1 is arranged below the mechanical cooling sub-module. That is, the natural cooling sub-module is closer to the ground than the mechanical cooling sub-module. Of course, in some embodiments, the natural cooling sub-module may also be arranged above the mechanical cooling sub-module.

In implementation, the ordinary evaporative cooling coil of the natural cooling sub-module and the fluorine pump evaporative cooling coil of the mechanical cooling sub-module may be cooled by a combined action of the outdoor air cooled by the precooling wet film and the indirect evaporative cooler and the cooling water cooled by the direct evaporative heat exchanger. In this way, the coils of the plurality of cooling sub-modules can act at an operating temperature with higher energy efficiency.

In implementation, a precooling part of the indirect evaporative cooling uses an indirect evaporative cooling principle for temperature reduction. The combined action of the outdoor air precooled and the spray system can achieve the objective of cooling the air on a precooling side, and then the outdoor air is discharged into the atmosphere through the guidance of the air precooler.

Based on the same technical idea, an embodiment of the present disclosure also provides a data center, which includes the compound evaporative cooling tower and a server room. The cooling tower is arranged outside the server room to cool the server room.

By adopting the above embodiment, the present disclosure can at least produce following technical effects.

Compared with the traditional evaporative cooling system air conditioner, by using the compound evaporative cooling principles, the compound evaporative cooling tower and the data center provided by the present disclosure can improve the cooling efficiency of the air conditioner system, and further reduce the energy consumption in the operation of the data center. In addition, the present disclosure integrates multiple sets of standalone cold sources to cool the same data center, thus further improving the cooling effect of the air conditioning system and realizing rapid delivery of the air conditioning system based on cooling by the multiple sets of cold sources.

The embodiments described above are merely preferred embodiments of the present disclosure, and are not intended to limit the present disclosure. All modifications, equivalent substitutions and improvements made within the spirit and principles of the present disclosure shall fall within the protection scope of the present disclosure.

What is claimed is:

1. A compound evaporative cooling tower comprising an air-inlet grille, a precooling module, a first spray module, a cooling module, a direct evaporative heat exchanger, a second spray module, a water collector, and an outdoor fan; wherein
the precooling module is arranged on an inner side of the air-inlet grille;
the first spray module is arranged above the precooling module, and the second spray module is arranged above the direct evaporative heat exchanger; and
the cooling module is arranged below the direct evaporative heat exchanger, and the cooling module comprises a plurality of cooling sub-modules.

2. The cooling tower of claim 1, wherein the precooling module comprises a precooling wet film and an indirect evaporative cooler arranged on an inner side of the precooling wet film.

3. The cooling tower of claim 1 further comprising at least one spray circulating pump, wherein the first spray module and the second spray module are connected to the at least one spray circulating pump through a pipe.

4. The cooling tower of claim 3, wherein the first spray module is connected to a first spray circulating pump, and the second spray module is connected to a second spray circulating pump.

5. The cooling tower of claim 1, wherein the cooling module comprises a natural cooling sub-module and a mechanical cooling sub-module.

6. The cooling tower of claim 5, wherein the natural cooling sub-module comprises an ordinary evaporative cooling coil and a cooling water circulating pump connected through a pipe.

7. The cooling tower of claim 5, wherein the mechanical cooling sub-module comprises a fluorine pump evaporative cooling coil, a fluorine pump, and a compressor connected through a pipe.

8. The cooling tower of claim 1 wherein the water collector is arranged above the second spray module, and the outdoor fan is arranged at a top of the cooling tower.

9. The cooling tower of claim 1, wherein the cooling tower further comprises an air precooler arranged above the first spray module.

10. A data center comprising a compound evaporative cooling tower and a server room, wherein the compound evaporative cooling tower comprises an air-inlet grille, a precooling module, a first spray module, a cooling module, a direct evaporative heat exchanger, a second spray module, a water collector, and an outdoor fan; wherein
the precooling module is arranged on an inner side of the air-inlet grille;
the first spray module is arranged above the precooling module, and the second spray module is arranged above the direct evaporative heat exchanger; and
the cooling module is arranged below the direct evaporative heat exchanger, and the cooling module comprises a plurality of cooling sub-modules.

11. The data center of claim 10, wherein the precooling module comprises a precooling wet film and an indirect evaporative cooler arranged on an inner side of the precooling wet film.

12. The data center of claim 10 further comprising at least one spray circulating pump, wherein the first spray module and the second spray module are connected to the at least one spray circulating pump through a pipe.

13. The data center of claim 12, wherein the first spray module is connected to a first spray circulating pump, and the second spray module is connected to a second spray circulating pump.

14. The data center of claim 10, wherein the cooling module comprises a natural cooling sub-module and a mechanical cooling sub-module.

15. The data center of claim 14, wherein the natural cooling sub-module comprises an ordinary evaporative cooling coil and a cooling water circulating pump connected through a pipe.

16. The data center of claim 14, wherein the mechanical cooling sub-module comprises a fluorine pump evaporative cooling coil, a fluorine pump, and a compressor connected through a pipe.

17. The data center of claim 10 wherein the water collector is arranged above the second spray module, and the outdoor fan is arranged at a top of the cooling tower.

18. The data center of claim 10, wherein the cooling tower further comprises an air precooler arranged above the first spray module.
